(19) United States
(12) Patent Application Publication
(10) Pub. No.: US 2024/0397643 A1
(43) Pub. Date: Nov. 28, 2024

(54) DISPLAY DEVICE

(71) Applicant: SAMSUNG DISPLAY CO., LTD., YONGIN-SI (KR)

(72) Inventors: Joong Gun JEONG, Yongin-si (KR); Jung Il LEE, Yongin-si (KR); Min Sung KIM, Yongin-si (KR); Ji Heon LEE, Yongin-si (KR)

(21) Appl. No.: 18/594,100

(22) Filed: Mar. 4, 2024

(30) Foreign Application Priority Data
May 24, 2023 (KR) 10-2023-0066966

(51) Int. Cl. H05K 5/02; H05K 5/00

(52) U.S. Cl. CPC H05K 5/02; H05K 5/0018

(57) ABSTRACT

A display device includes a display panel that is foldable based on a folding line extending in a first direction. A support member is on a first surface of the display panel and includes first and second non-folding parts, a folding part disposed therebetween which is stretched when the display panel is folded and a groove disposed on the folding part. The folding part includes slits and bars disposed between the slits. The support member includes fiber yarns extending in the first direction and fiber yarns extending in a second direction crossing the first direction. The fiber yarns extending in the first direction and the fiber yarns extending in the second direction are alternately stacked along a thickness direction of the support member. The slits and the fiber yarns on an upper surface of the folding part exposed by the groove have a same extension direction as each other.

### CROSS-REFERENCE TO RELATED APPLICATION

This application claims priority under 35 U.S.C. § 119 to Korean Patent Application No. 10-2023-0066966, filed on May 24, 2023 in the Korean Intellectual Property Office, the disclosure of which is incorporated by reference in its entirety.

### 1. TECHNICAL FIELD

The present disclosure relates to a display device.

### 2. DISCUSSION OF RELATED ART

The demand for display devices for displaying images has increased and the types of electronic devices that the display devices are applied to have diversified with the development of the information society. For example, display devices have been applied to various electronic devices such as smartphones, digital cameras, laptop computers, navigation devices, and smart televisions.

Recently, to increase the portability of the display devices and provide wide display screens, bendable display devices in which a display area may be bent or foldable display devices in which a display area may be folded have been released.

Research and development for technologies using fiber reinforced plastics (FRP) or metal plates as panel support members supporting flexible displays of the display devices have also been actively conducted.

### SUMMARY

Aspects of the present disclosure provide a display device having a reduced thickness while increasing impact resistance characteristics.

Aspects of the present disclosure also provide a display device in which reliability of a panel support member is increased.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a display panel that is foldable based on a folding line extending in a first direction. A support member is disposed on a first surface of the display panel and includes a folding part that is stretched when the display panel is folded, a first non-folding part and a second non-folding part disposed on a first side and an opposite second side of the folding part, respectively, and a groove disposed on the folding part. The folding part includes a plurality of slits and a plurality of bars disposed between the plurality of slits. The support member includes fiber yarns extending in the first direction and fiber yarns extending in a second direction crossing the first direction. The fiber yarns extending in the first direction and the fiber yarns extending in the second direction are alternately stacked along a thickness direction of the support member. The plurality of slits and the fiber yarns on an upper surface of the folding part exposed by the groove have a same extension direction as each other.

In an embodiment, the folding line has a same extension direction as the extension direction of the plurality of slits.

In an embodiment, thicknesses of each of the first non-folding part and the second non-folding part are greater than a thickness of the folding part.

In an embodiment, the support member includes, a first layer having first fiber yarns extending in the first direction, a second layer disposed directly on the first layer and having second fiber yarns extending in the second direction crossing the first direction, a third layer disposed directly on the second layer and having third fiber yarns extending in the first direction, and a fourth layer disposed directly on the third layer and having fourth fiber yarns extending in the second direction. The upper surface of the folding part is positioned at a same height as the third layer.

In an embodiment, the display device of claim 1, a thickness of the groove is greater than a thickness of the fourth layer.

In an embodiment, the thickness of the groove is in a range of about 50 μm to about 80 μm, and the thickness of the fourth layer is in a range of about 25 μm to about 75 μm.

In an embodiment, the groove overlaps the third layer and the fourth layer.

In an embodiment, the first layer, the second layer, the third layer, and the fourth layer have a same thickness as each other.

In an embodiment, the support member further includes a fifth layer disposed directly on the fourth layer. The fifth layer having fifth fiber yarns extending in the first direction. The groove further overlaps the fifth layer.

In an embodiment, a thickness of the groove is greater than a sum of thicknesses of the fourth layer and the fifth layer.

In an embodiment, the folding part is positioned at a same height as the first layer, the second layer, and the third layer.

In an embodiment, the display device may further comprise a lower member disposed between the display panel and the support member. The lower member is disposed within the groove.

In an embodiment, the lower member includes at least one of a light blocking layer, a buffer layer, and a shielding layer.

In an embodiment, the display device may further comprise a digitizer member disposed on a surface of the support member. The digitizer member overlaps the first non-folding part and the second non-folding part.

In an embodiment, the support member includes, a first layer having first fiber yarns extending in the first direction, a second layer disposed on the first layer and having second fiber yarns extending in the second direction crossing the first direction, and a third layer disposed on the second layer and having third fiber yarns extending in the first direction. A thickness of the third layer is greater than thicknesses of the first layer and the second layer.

In an embodiment, a thickness of the groove is less than the thickness of the third layer. In an embodiment, the fiber yarns include at least one of carbon fibers and glass fibers.

According to an embodiment of the present disclosure, a display panel includes a folding area, a first non-folding area disposed on a first side of the folding area, and a second non-folding area disposed on an opposite second side of the folding area. A support member is disposed on a first surface of the display panel. The support member includes a groove disposed in the folding area and a folding part disposed below the groove. The folding part includes a plurality of slits. The support member includes a first layer having first fiber yarns extending in a first direction. A second layer is disposed on the first layer and has second fiber yarns extending in a second direction crossing the first direction. A third layer is disposed on the second layer and has third fiber yarns extending in the first direction. The plurality of slits exposed by the groove extends in the first direction.

In an embodiment, an upper surface of the folding part is positioned at a same height as the third layer.

In an embodiment, the display device may further comprise a lower member disposed between the display panel and the support member. The lower member is disposed within the groove.

With a display device according to an embodiment of the present disclosure, it is possible to reduce a thickness of the display device while increasing impact resistance characteristics.

With the display device according to an embodiment of the present disclosure, it is possible to increase reliability of a panel support member.

The effects of embodiments of the present disclosure are not necessarily limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating an unfolded state of a display device according to an embodiment;

FIG. 2 is a perspective view illustrating a folded state of the display device according to an embodiment;

FIG. 3 is a perspective view illustrating an unfolded state of a display device according to an embodiment;

FIG. 4 is a perspective view illustrating a folded state of the display device according to an embodiment;

FIG. 5 is an exploded perspective view illustrating the display device according to an embodiment;

FIG. 6 is a cross-sectional view taken along line X1-X1′ of FIG. 5 according to an embodiment;

FIG. 7 is a cross-sectional view illustrating a display panel according to an embodiment;

FIG. 8 is a perspective view of a panel support member according to an embodiment;

FIG. 9 is a plan view of the panel support member according to an embodiment;

FIG. 10 is a cross-sectional view taken along line X2-X2′ of FIG. 9 according to an embodiment;

FIG. 11 is a cross-sectional view taken along line X3-X3′ in FIG. 9 according to an embodiment;

FIG. 12 is an enlarged view of portion A of FIG. 9 according to an embodiment;

FIG. 13 is an enlarged view of a folding part of a display device according to a comparative embodiment;

FIG. 14 is an enlarged view of a folding part of the display device according to an embodiment;

FIG. 15 is a perspective view of a panel support member according to an embodiment;

FIG. 16 is a cross-sectional view taken along line X4-X4′ in FIG. 15 according to an embodiment;

FIG. 17 is a perspective view of a panel support member according to an embodiment;

and

FIG. 18 is a cross-sectional view taken along line X5-X5′ of FIG. 17 according to an embodiment.

### DETAILED DESCRIPTION OF EMBODIMENTS

The present disclosure will now be described more fully hereinafter with reference to the accompanying drawings, in which non-limiting embodiments of the invention are shown. The present disclosure may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification.

Hereinafter, embodiments of the present disclosure will be described in detail with reference to the accompanying drawings.

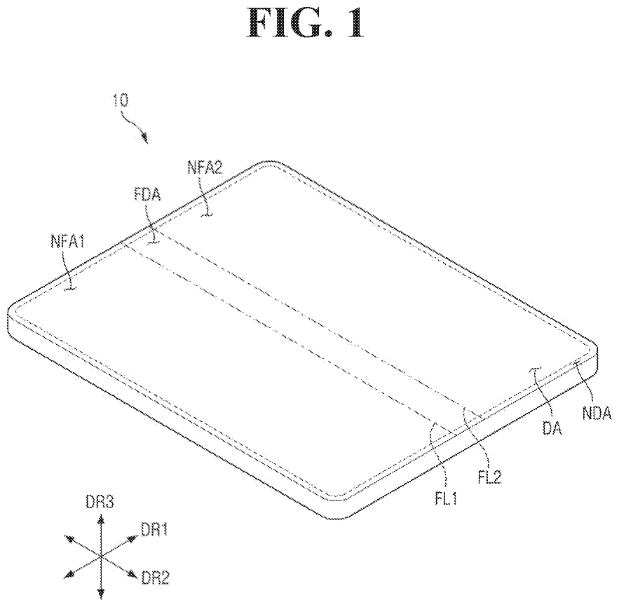

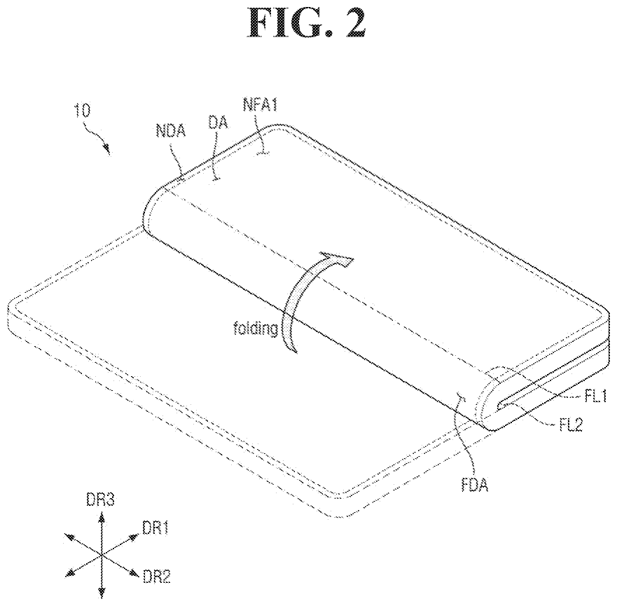

FIG. 1 is a perspective view illustrating an unfolded state of a display device according to an embodiment. FIG. 2 is a perspective view illustrating a folded state of the display device according to an embodiment.

Referring to FIGS. 1 and 2, a first state of a display device 10 that is not bent at first and second folding lines FL1 and FL2 and is unfolded is illustrated in FIG. 1, and a second state of the display device 10 that is bent at the first and second folding lines FL1 and FL2 is illustrated in FIG. 2.

The display device 10 according to an embodiment is a device that displays at least one moving image and/or still image, and may be used as a display screen of each of various products such as televisions, laptop computers, monitors, billboards, and the Internet of Things (IoT) as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). However, embodiments of the present disclosure are not necessarily limited thereto.

In FIGS. 1 and 2, a first direction DR1 is a direction parallel to one side of the display device 10 in a plan view (e.g., in a plane defined in the first and second directions DR1, DR2), and may be, for example, a transverse direction of the display device 10. A second direction DR2 is a direction parallel to the other side of the display device 10 in direct contact with the one side of the display device 10 in the plan view, and may be a longitudinal direction of the display device 10. A third direction DR3 may be a thickness direction of the display device 10. In an embodiment, the first to third directions DR1 to DR3 may be perpendicular to each other.

However, embodiments of the present disclosure are not necessarily limited thereto and the first to third directions DR1 to DR3 may cross each other at various different angles in some embodiments.

In an embodiment, the display device 10 may have a quadrangular shape such as a rectangular shape in a plan view. Each of corners of the display device 10 may have a right-angle shape in a plan view or a round shape in a plan view. In an embodiment, a front surface of the display device 10 may include two relatively short sides disposed in the first direction DR1 and two relatively long sides disposed in the second direction DR2.

The display device 10 may include a display area DA and a non-display area NDA. In an embodiment, a shape of the display area DA in plan view may follow the shape of the display device 10 in plan view. For example, in an embodiment in which the shape of the display device 10 in plan view is the rectangular shape, the shape of the display area DA in plan view may also be a rectangular shape. However, embodiments of the present disclosure are not necessarily limited thereto.

The display area DA may be an area displaying an image by including a plurality of pixels. The non-display area NDA may be an area that does not display an image and does not include pixels. The non-display area NDA may be disposed around the display area DA (e.g., in the first and/or second directions DR1, DR2). In an embodiment, the non-display area NDA may be disposed to surround the display area DA (e.g., fully surround the display area DA in the first and second directions DR1, DR2). However, embodiments of the present disclosure are not necessarily limited thereto. For example, in some embodiments the display area DA may be partially surrounded by the non-display area NDA.

The display device 10 may be foldable in which the display device 10 may be maintained in both a first state, which is an unfolded state, and a second state, which is a bent state. The display device 10 may be folded in an in-folding manner so that the display areas DA face each other, as illustrated in FIG. 2. In this embodiment, front surfaces of the display device 10 may face each other when the display device 10 is folded. Alternatively, the display device 10 may be folded in an out-folding manner so that rear surfaces thereof face each other.

The display device 10 may include a folding area FDA, a first non-folding area NFA1, and a second non-folding area NFA2. The folding area FDA may be an area in which the display device 10 is bent or folded, and the first non-folding area NFA1 and the second non-folding area NFA2 may be areas in which the display device 10 is not bent or folded. In an embodiment, the first non-folding area NFA1 and the second non-folding area NFA2 may be flat areas of the display device 10.

The first non-folding area NFA1 may be disposed on one side (e.g., a first side), for example, the left side, of the folding area FDA. The second non-folding area NFA2 may be disposed on the other side (e.g., an opposite second side), for example, the right side, of the folding area FDA. In an embodiment, the folding area FDA is an area defined by a first folding line FL1 and a second folding line FL2, and may be an area in which the display device 10 is bent with a predetermined curvature. The first folding line FL1 may be a boundary between the folding area FDA and the first non-folding area NFA1, and the second folding line FL2 may be a boundary between the folding area FDA and the second non-folding area NFA2.

In an embodiment, the first folding line FL1 and the second folding line FL2 may extend in the second direction DR2 as illustrated in FIGS. 1 and 2, and in this embodiment, the display device 10 may be folded along the first direction DR1. Accordingly, a length of the display device 10 in the first direction DR1 may be reduced by approximately half, and thus, a user may conveniently carry the display device 10.

In an embodiment in which the first folding line FL1 and the second folding line FL2 extend in the second direction DR2 as illustrated in FIGS. 1 and 2, a length of the folding area FDA in the second direction DR2 may be greater than a length of the folding area FDA in the first direction DR1. In addition, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

Each of the display area DA and the non-display area NDA may overlap at least one of the folding area FDA, the first non-folding area NFA1, and the second non-folding area NFA2. It has been illustrated in FIGS. 1 and 2 that each of the display area DA and the non-display area NDA overlaps the folding area FDA, the first non-folding area NFA1, and the second non-folding area NFA2. However, embodiments of the present disclosure are not necessarily limited thereto.

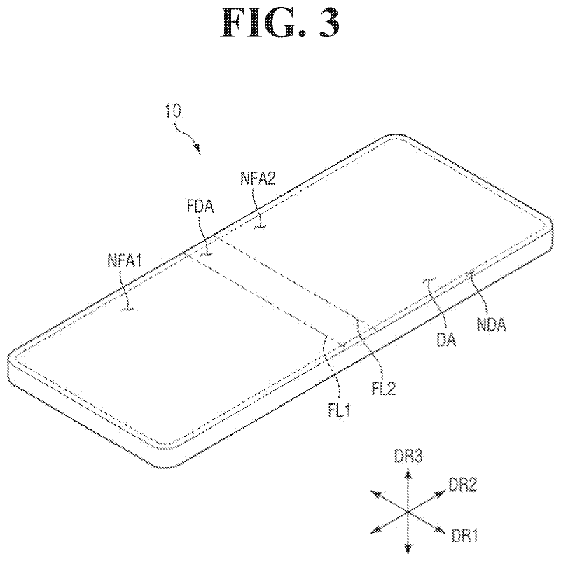

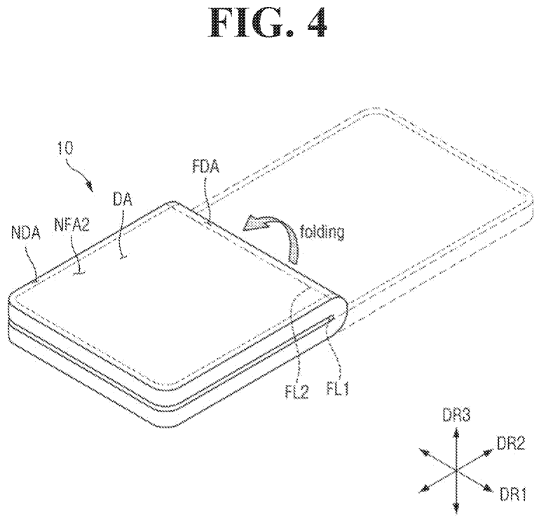

FIG. 3 is a perspective view illustrating an unfolded state of a display device according to an embodiment. FIG. 4 is a perspective view illustrating a folded state of the display device according to an embodiment.

The embodiments of FIGS. 3 and 4 are different from embodiments of FIGS. 1 and 2 in that the first folding line FL1 and the second folding line FL2 extend in the first direction DR1, and the display device 10 is folded in the second direction DR2, and thus, a length of the display device 10 in the second direction DR2 is reduced by approximately half when the display device 10 is folded. Therefore, in FIGS. 3 and 4, a description overlapping a description of embodiments of FIGS. 1 and 2 will be omitted for economy of description.

Referring to FIGS. 3 and 4, a first state of a display device 10 that is not bent at the first and second folding lines FL1 and FL2 and is unfolded is illustrated in FIG. 3, and a second state of the display device 10 that is bent at the folding lines FL1 and FL2 is illustrated in FIG. 4.

In the first state in which the display device 10 is unfolded, relatively long sides of the display device 10 may extend along the second direction DR2, and relatively short sides of the display device 10 may extend along the first direction DR1.

The first folding line FL1 and the second folding line FL2 may extend in the first direction DR1 as illustrated in FIGS. 3 and 4, and in this embodiment the display device 10 may be folded along the second direction DR2.

The first non-folding area NFA1 may be disposed on one side, for example, the lower side, of the folding area FDA (e.g., in the second direction DR2). The second non-folding area NFA2 may be disposed on the other side, for example, the upper side, of the folding area FDA (e.g., in the second direction DR2).

In an embodiment in which the first folding line FL1 and the second folding line FL2 extend in the first direction DR1 as illustrated in FIGS. 3 and 4, a length of the folding area FDA in the first direction DR1 may be greater than a length of the folding area FDA in the second direction DR2. In addition, a length of the first non-folding area NFA1 in the second direction DR2 may be greater than a length of the first non-folding area NFA1 in the first direction DR1. A length of the second non-folding area NFA2 in the second direction DR2 may be greater than a length of the second non-folding area NFA2 in the first direction DR1.

Hereinafter, for convenience of explanation, an embodiment of FIGS. 1 and 2 will be described as an example. However, embodiments of the present disclosure are not necessarily limited thereto, and the following contents may be equally applied to embodiments of FIGS. 3 and 4.

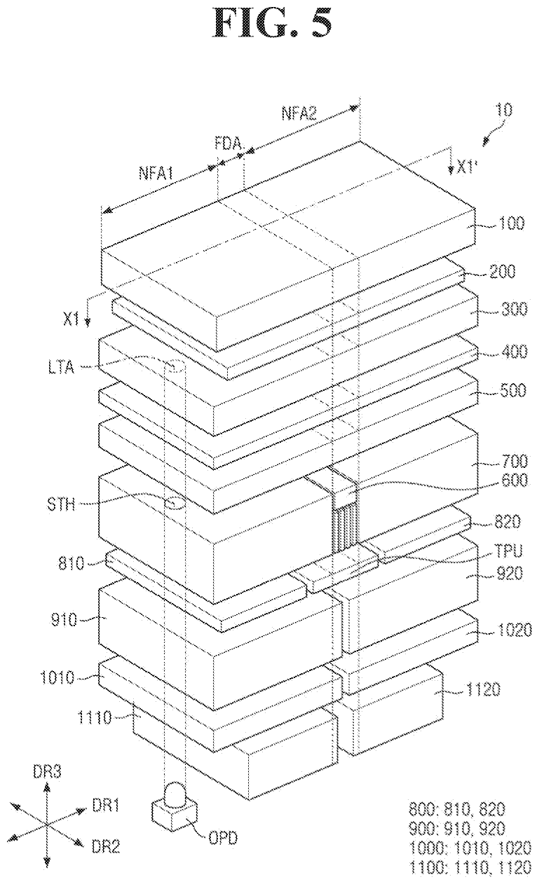

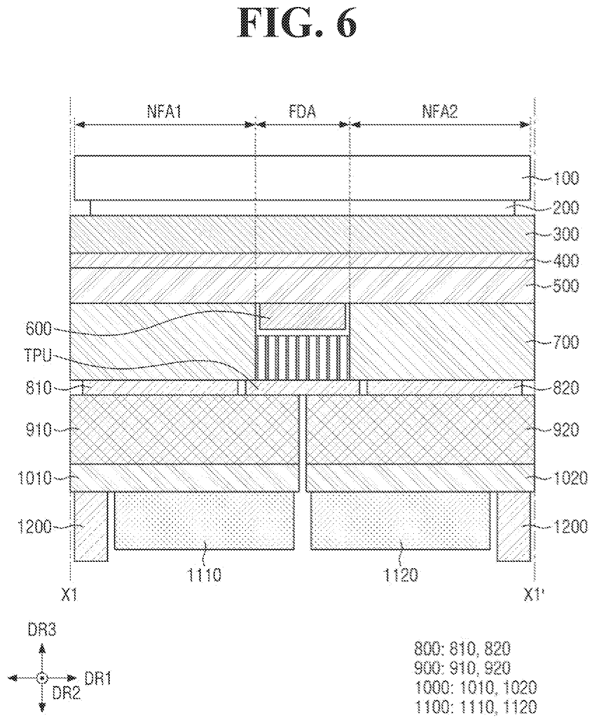

FIG. 5 is an exploded perspective view illustrating the display device according to an embodiment. FIG. 6 is a cross-sectional view taken along line X1-X1′ of FIG. 5.

Referring to FIGS. 5 and 6, the display device 10 according to an embodiment may include an upper protection member 100, a window member 200, a first adhesive member 300, a display panel 400, a panel protection member 500, a panel lower member 600, a panel support member 700, a second adhesive member 800, a digitizer member 900, a metal support member 1000, a buffer member 1100, and a third adhesive member 1200.

The display panel 400 may be a panel that displays an image. In an embodiment, the display panel 400 may be an organic light emitting display panel including an organic light emitting layer, a quantum dot light emitting display panel including a quantum dot light emitting layer, an inorganic light emitting display panel using inorganic semiconductor elements as light emitting elements, and a micro light emitting display panel using micro light emitting diodes as light emitting elements. Hereinafter, the display panel 400 will be mainly described an organic light emitting display panel for convenience of explanation. However, embodiments of the present disclosure are not necessarily limited thereto.

In an embodiment the display panel 400 may include a light transmission area LTA overlapping an optical device OPD in the third direction DR3. The optical device OPD is an optical sensor that senses light, and may be, for example, a camera sensor, a proximity sensor, and an illuminance sensor. However, embodiments of the present disclosure are not necessarily limited thereto. The light transmission area LTA may be a portion of the display area DA.

In an embodiment, the light transmission area LTA may include a transmission area capable of transmitting light therethrough. Alternatively, the light transmission area LTA may be a through hole penetrating through the display panel. Light transmittance of the light transmission area LTA may be higher than the light transmittance of the remaining portions of the display area DA excluding the light transmission area LTA. In addition, due to the transmission area of the light transmission area LTA, a density or a degree of integration of pixels in the light transmission area LTA may be lower than a density or a degree of integration of pixels in the display area DA excluding the light transmission area LTA. For example, the number of pixels per unit area in the light transmission area LTA may be less than the number of pixels per unit area in the display area DA excluding the light transmission area LTA. Alternatively, pixels per inch (PPI) in the light transmission area LTA may be less than pixels per inch (PPI) in the display area DA excluding the light transmission area LTA.

The window member 200 may be attached to a front surface of the display panel 400 by the first adhesive member 300. In an embodiment, the window member 200 may be made of a transparent material such as glass or plastic. For example, the window member 200 may be an ultra thin glass (UTG) having a thickness of about 0.1 mm or less or a transparent polyimide film. In an embodiment, the first adhesive member 300 may be a transparent adhesive film or a transparent adhesive resin.

The upper protection member 100 may be disposed on a front surface of the window member 200. The upper protection member 100 may be attached to the front surface of the window member 200. In an embodiment, the upper protection member 100 may perform at least one of a scattering prevention function of the window member 200, an impact absorption function, a chopping prevention function, a fingerprint prevention function, and a glare prevention function. However, embodiments of the present disclosure are not necessarily limited thereto.

In an embodiment, a light blocking pattern may be formed on a rear surface of the upper protection member 100. The light blocking pattern may be disposed at an edge of the upper protection member 100 or be disposed adjacent to the edge of the upper protection member 100. The light blocking pattern may include a light blocking material capable of blocking light. For example, in an embodiment the light blocking pattern may be made of an inorganic black pigment such as carbon black, an organic black pigment, or an opaque metal material. However, embodiments of the present disclosure are not necessarily limited thereto.

The panel protection member 500 may be disposed on (e.g., disposed directly thereon) a rear surface of the display panel 400. The panel protection member 500 may serve to support the display panel 400 and may protect the rear surface of the display panel 400. In an embodiment, the panel protection member 500 may be made of plastic such as polyethylene terephthalate (PET) or polyimide. It has been illustrated in FIGS. 5 and 6 that the panel protection member 500 is also disposed in the folding area FDA of the display device 10. However, embodiments of the present disclosure are not necessarily limited thereto. For example, in an embodiment the panel protection member 500 may be removed in the folding area FDA of the display device 10 to permit the display device 10 to be smoothly folded.

The panel lower member 600 may be disposed on (e.g., disposed directly thereon) a rear surface of the panel protection member 500. The panel lower member 600 may include at least one of a light blocking layer for absorbing light incident from the outside, a buffer layer for absorbing external impact, and a heat dissipation layer (e.g., a shielding layer) for efficiently dissipating heat of the display panel 400.

The light blocking layer blocks transmission of the light to prevent components, for example, the digitizer member 900 and the like, disposed below the light blocking layer from being viewed from above the display panel 400. In an embodiment, the light blocking layer may include a light absorbing material such as a black pigment or a black dye. However, embodiments of the present disclosure are not necessarily limited thereto.

The buffer layer absorbs the external impact to prevent the display panel 400 from being damaged. The buffer layer may be formed as a single layer or a plurality of layers. For example, in an embodiment the buffer layer may be made of a polymer resin such as polyurethane, polycarbonate, polypropylene, or polyethylene or may include a material having elasticity, such as a sponge formed by foaming rubber, a urethane-based material, or an acrylic material. However, embodiments of the present disclosure are not necessarily limited thereto.

The heat dissipation layer may include a first heat dissipation layer including graphite, carbon nanotubes, or the like, and a second heat dissipation layer formed as a thin metal film such as copper, nickel, ferrite, or silver that may shield electromagnetic waves and has a high thermal conductivity.

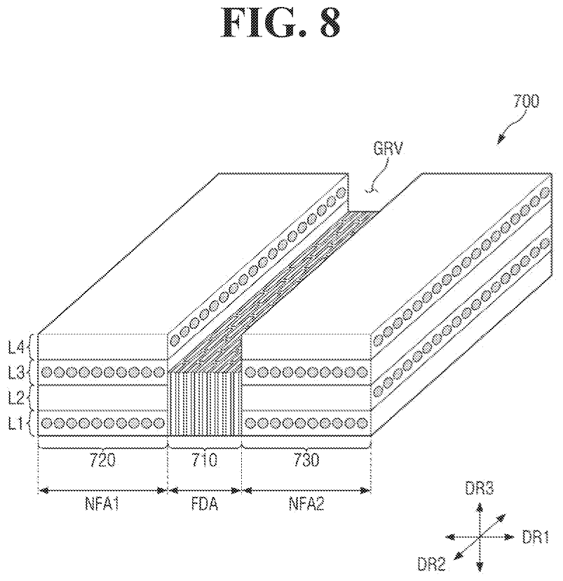

In the display device 10 according to an embodiment, the panel lower member 600 may be disposed within a groove GRV (see FIG. 8) of the panel support member 700. Accordingly, it is possible to reduce a thickness of the display device 10 while increasing impact resistance characteristics such as light blocking, buffering, and heat dissipation.

The panel support member 700 may be disposed on (e.g., disposed directly thereon) the rear surface of the panel protection member 500. The panel support member 700 may be a rigid member having a shape or volume that does not change easily due to an external pressure. Since the panel support member 700 is disposed on the rear surface of the display panel 400 and is the rigid member having a shape or volume that does not change easily due to the external pressure, the panel support member 700 may support the display panel 400.

In an embodiment, the panel support member 700 may be made of a polymer including carbon fibers or glass fibers. In this embodiment, since the panel support member 700 is made of the polymer including the carbon fibers or the glass fibers, the panel support member 700 may pass magnetic fields or electromagnetic signals of the digitizer member 900 therethrough. Therefore, the panel support member 700 capable of supporting the display panel 400 without lowering touch sensitivity of the digitizer member 900 may be provided.

In an embodiment, the panel support member 700 may be a metal plate. For example, the panel support member 700 is a metal plate, and may be made of a metal or a metal alloy. In an embodiment, the panel support member 700 may include copper (Cu), aluminum (Al), stainless steel (SUS), and/or alloys thereof. However, embodiments of the present disclosure are not necessarily limited thereto.

Hereinafter, for convenience of explanation, an embodiment in which the panel support member 700 is made of the polymer including the carbon fibers or the glass fibers will be described for convenience of explanation. However, embodiments of the present disclosure are not necessarily limited thereto.

The panel support member 700 may include a through hole STH overlapping the optical device OPD in the third direction DR3. The through hole STH may overlap the light transmission area LTA of the display panel 400 in the third direction DR3. In an embodiment, an area of the through hole STH may be greater than an area of the light transmission area LTA. The optical device OPD may sense light incident from a front surface of the display device 10 through the light transmission area LTA and the through hole STH.

The panel support member 700 may include a grating pattern disposed in the folding area FDA so as to be easily bent in the folding area FDA. The panel support member 700 may include the grating pattern disposed in the folding area FDA, and may thus be easily bent when the display device 10 is folded.

The panel support member 700 will be described later in detail with reference to FIG. 8 and the like.

A lower viewing prevention member TPU may be disposed on a rear surface of the panel support member 700. The lower viewing prevention member TPU may be disposed to overlap the folding area FDA. In an embodiment, the lower viewing prevention member TPU may be disposed at the same layer (e.g., in the third direction DR3) as the second adhesive member. The lower viewing prevention member TPU may be disposed between a second-first adhesive member 810 and a second-second adhesive member 820 (e.g., in the first direction DR1). The lower viewing prevention member TPU may prevent the grating pattern of the panel support member 700 from being viewed to the outside. In an embodiment, the lower viewing prevention member TPU may include a flexible material to reduce folding stress of the display device 10.

The digitizer member 900 may include a first digitizer member 910 and a second digitizer member 920. The first digitizer member 910 and the second digitizer member 920 may be disposed on the rear surface of the panel support member 700. The first digitizer member 910 and the second digitizer member 920 may be attached to the rear surface of the panel support member 700 by the second adhesive member 800.

In an embodiment, the second adhesive member 800 may be a pressure sensitive adhesive. In an embodiment, the second adhesive member 800 may include the second-first adhesive member 810 overlapping the first digitizer member 910 (e.g., in the third direction DR3) and the second-second adhesive member 820 overlapping the second digitizer member 920 (e.g., in the third direction DR3).

In an embodiment, the first digitizer member 910 and the second digitizer member 920 may not be disposed in the folding area FDA to reduce the folding stress of the display device 10. The first digitizer member 910 may be disposed in the first non-folding area NFA1, and the second digitizer member 920 may be disposed in the second non-folding area NFA2. In an embodiment, a gap between the first digitizer member 910 and the second digitizer member 920 may overlap the folding area FDA, and may be less than a width of the folding area FDA. The width of the folding area FDA may be a length of the folding area FDA in the first direction DR1.

In an embodiment, the first digitizer member 910 and the second digitizer member 920 may include electrode patterns for sensing approach or contact of an electronic pen such as a stylus pen supporting electromagnetic resonance (EMR). The first digitizer member 910 and the second digitizer member 920 may sense magnetic fields or electromagnetic signals emitted from the electronic pen based on the electrode patterns, and determine a point where the sensed magnetic field or electromagnetic signal is the greatest as a touch coordinate.

In an embodiment, magnetic metal powders may be disposed on a rear surface of the first digitizer member 910 and a rear surface of the second digitizer member 920. In this embodiment, the magnetic fields or the electromagnetic signals passing through the first digitizer member 910 and the second digitizer member 920 may flow into the magnetic metal powders. Therefore, due to the magnetic metal powders, a phenomenon in which the magnetic fields or the electromagnetic signals of the first digitizer member 910 and the second digitizer member 920 are emitted to a rear surface of the display device 10 may be reduced.

The metal support member 1000 may include a first metal support member 1010 and a second metal support member 1020. In an embodiment, the first metal support member 1010 may be disposed on the rear surface of the first digitizer member 910, and the second metal support member 1020 may be disposed on the rear surface of the second digitizer member 920.

In an embodiment, the first metal support member 1010 and the second metal support member 1020 may not be disposed in the folding area FDA to reduce the folding stress of the display device 10. The first metal support member 1010 may be disposed in the first non-folding area NFA1, and the second metal support member 1020 may be disposed in the second non-folding area NFA2. In an embodiment, a gap between the first metal support member 1010 and the second metal support member 1020 may overlap the folding area FDA, and may be less than the width of the folding area FDA.

The first metal support member 1010 and the second metal support member 1020 may include a material having high rigidity to support the first digitizer member 910 and the second digitizer member 920, respectively. For example, in an embodiment the first metal support member 1010 and the second metal support member 1020 may include stainless steel such as SUS316. However, embodiments of the present disclosure are not necessarily limited thereto.

In an embodiment, the buffer member 1100 may include a first buffer member 1110 and a second buffer member 1120. The first buffer member 1110 and the second buffer member 1120 may absorb external impact to prevent the panel support member 700 and the digitizer member 900 from being damaged. In an embodiment, the first buffer member 1110 and the second buffer member 1120 may include a material having elasticity, such as a sponge formed by foaming rubber, a urethane-based material, or an acrylic material. However, embodiments of the present disclosure are not necessarily limited thereto.

In an embodiment, the first buffer member 1110 may be disposed on (e.g., disposed directly thereon) a rear surface of the first metal support member 1010, and the second buffer member 1120 may be disposed on (e.g., disposed directly thereon) a rear surface of the second metal support member 1020. In an embodiment, the first buffer member 1110 and the second buffer member 1120 may not be disposed in the folding area FDA to reduce the folding stress of the display device 10. The first buffer member 1110 may be disposed in the first non-folding area NFA1, and the second buffer member 1120 may be disposed in the second non-folding area NFA2. In an embodiment, a gap between the first buffer member 1110 and the second buffer member 1120 may overlap the folding area FDA, and may be less than the width of the folding area FDA.

In an embodiment, the third adhesive member 1200 may be disposed on (e.g., disposed directly thereon) a portion of the rear surface of the first metal support member 1010 and the rear surface of the second metal support member 1020. For example, the third adhesive member 1200 may be disposed on (e.g., disposed directly thereon) an edge of the first metal support member 1010 and an edge of the second metal support member 1020. The third adhesive member 1200 may be disposed to surround the first buffer member 1110 and the second buffer member 1120.

In an embodiment, the third adhesive member 1200 may be a waterproof tape or a waterproof member attaching the rear surface of the first metal support member 1010 to a front surface of a frame disposed on a rear surface of the buffer member 1100. Accordingly, permeation of moisture or dust into the display device 10 may be prevented by the third adhesive member 1200. For example, the display device 10 capable of being waterproof and dustproof may be provided.

However, embodiments of the present disclosure are not necessarily limited thereto. For example, in an embodiment, the third adhesive member 1200 does not surround the first buffer member 1110 and the second buffer member 1120, and may be disposed to overlap a magnet for maintaining the folding of the display device 10 in the third direction DR3. In this embodiment, the third adhesive member 1200 may serve as a magnetism shielding member capable of shielding magnetism of the magnet to prevent the digitizer member 900 or the display panel 400 from being affected by the magnetism.

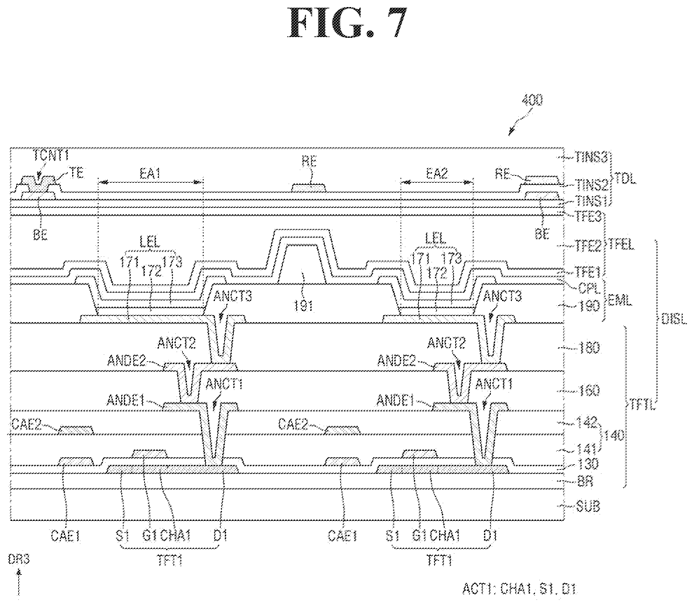

FIG. 7 is a cross-sectional view illustrating an example of a display panel according to an embodiment.

Referring to FIG. 7, the display panel 400 may include a substrate SUB, a display layer DISL disposed on the substrate SUB, and a touch sensing layer TDL disposed on the display layer DISL. In an embodiment, the display layer DISL may include a thin film transistor layer TFTL, a light emitting element layer EML, and an encapsulation layer TFEL.

The thin film transistor layer TFTL may be disposed on the substrate SUB (e.g., disposed directly thereon in the third direction DR3). In an embodiment, the thin film transistor layer TFTL may include a barrier film BR, thin film transistors TFT1, first capacitor electrodes CAE1, second capacitor electrodes CAE2, first anode connection electrodes ANDE1, second anode connection electrodes ANDE2, a gate insulating film 130, a first interlayer insulating film 141, a second interlayer insulating film 142, a first planarization film 160, and a second planarization film 180.

In an embodiment, the substrate SUB may be made of an insulating material such as a polymer resin. For example, the substrate SUB may be made of polyimide. The substrate SUB may be a flexible substrate that may be bent, folded, and rolled.

The barrier film BR may be disposed on the substrate SUB (e.g., disposed directly thereon in the third direction DR3). The barrier film BR is a film for protecting thin film transistors of the thin film transistor layer TFTL and the light emitting layer 172 of the light emitting element layer EML from moisture permeating through the substrate SUB vulnerable to moisture permeation. In an embodiment, the barrier film BR may include a plurality of inorganic films that are alternately stacked. For example, the barrier film BR may be formed as multiple films in which one or more inorganic films of a silicon nitride layer, a silicon oxynitride layer, a silicon oxide layer, a titanium oxide layer, and an aluminum oxide layer are alternately stacked.

The thin film transistors TFT1 may be disposed on the barrier film BR (e.g., disposed directly thereon in the third direction DR3). Active layers ACT1 of the thin film transistors TFT1 may be disposed on (e.g., directly thereon) the barrier film BR. In an embodiment, the active layer ACT1 of the thin film transistor TFT1 may include polycrystalline silicon, single crystal silicon, low-temperature polycrystalline silicon, amorphous silicon, or an oxide semiconductor. However, embodiments of the present disclosure are not necessarily limited thereto.

The active layer ACT1 may include a channel region CHA1, a source region S1, and a drain region D1. The channel region CHA1 may be a region overlapping a gate electrode G1 in the third direction DR3, which is a thickness direction of the substrate SUB. The source region S1 may be disposed on one lateral side of the channel region CHA1, and the drain region D1 may be disposed on the other lateral side of the channel region CHA1. The source region S1 and the drain region D1 may be regions that do not overlap the gate electrode G1 in the third direction DR3. In an embodiment, the source region S1 and the drain region D1 may be regions having conductivity by doping a silicon semiconductor or an oxide semiconductor with ions or impurities.

The gate insulating film 130 may be disposed on (e.g., disposed directly thereon) the active layer ACT1 of the thin film transistor TFT1. In an embodiment, the gate insulating film 130 may be formed as an inorganic film such as a silicon nitride layer, a silicon oxynitride layer, a silicon oxide layer, a titanium oxide layer, or an aluminum oxide layer. However, embodiments of the present disclosure are not necessarily limited thereto.

The gate electrodes G1 of the thin film transistors TFT1 and the first capacitor electrodes CAE1 may be disposed on (e.g., disposed directly thereon) the gate insulating film 130. The gate electrode G1 may overlap the channel region CHA1 in the third direction DR3. It has been illustrated in FIG. 7 that the gate electrode G1 and the first capacitor electrode CAE1 are disposed to be spaced apart from each other. However, in some embodiments the gate electrode G1 and the first capacitor electrode CAE1 may be connected to, and formed integrally with, each other. In an embodiment, each of the gate electrode G1 and the first capacitor electrode CAE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments of the present disclosure are not necessarily limited thereto.

The first interlayer insulating film 141 may be disposed on (e.g., disposed directly thereon) the gate electrodes G1 of the thin film transistors TFT1 and the first capacitor electrodes CAE1. In an embodiment, the first interlayer insulating film 141 may be formed as an inorganic film such as a silicon nitride layer, a silicon oxynitride layer, a silicon oxide layer, a titanium oxide layer, or an aluminum oxide layer. The first interlayer insulating film 141 may be formed as a plurality of inorganic films. However, embodiments of the present disclosure are not necessarily limited thereto.

The second capacitor electrodes CAE2 may be disposed on (e.g., disposed directly thereon) the first interlayer insulating film 141. The second capacitor electrode CAE2 may overlap the first capacitor electrode CAE1 in the third direction DR3. In addition, in an embodiment in which the gate electrode G1 and the first capacitor electrode CAE1 are formed integrally with each other, the second capacitor electrode CAE2 may overlap the gate electrode G1 in the third direction DR3. Since the first interlayer insulating film 141 has a predetermined dielectric constant, a capacitor may be formed by the first capacitor electrode CAE1, the second capacitor electrode CAE2, and the first interlayer insulating film 141 disposed between the first capacitor electrode CAE1 and the second capacitor electrode CAE2. In an embodiment, the second capacitor electrode CAE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments of the present disclosure are not necessarily limited thereto.

The second interlayer insulating film 142 may be disposed on (e.g., disposed directly thereon) the second capacitor electrodes CAE2. In an embodiment, the second interlayer insulating film 142 may be formed as an inorganic film such as a silicon nitride layer, a silicon oxynitride layer, a silicon oxide layer, a titanium oxide layer, or an aluminum oxide layer. The second interlayer insulating film 142 may be formed as a plurality of inorganic films.

The first anode connection electrodes ANDE1 may be disposed on (e.g., disposed directly thereon) the second interlayer insulating film 142. The first anode connection electrode

ANDE1 may be connected to the drain region D1 of the thin film transistor TFT1 through a first connection contact hole ANCT1 penetrating through the gate insulating film 130, the first interlayer insulating film 141, and the second interlayer insulating film 142. In an embodiment, the first anode connection electrode ANDE1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments of the present disclosure are not necessarily limited thereto.

The first planarization film 160 for planarizing a step due to the thin film transistors TFT1 may be disposed on (e.g., disposed directly thereon) the first anode connection electrodes ANDE1. In an embodiment, the first planarization film 160 may be formed as an organic film made of an acrylic resin, an epoxy resin, a phenolic resin, a polyamide resin, a polyimide resin, or the like. However, embodiments of the present disclosure are not necessarily limited thereto.

The second anode connection electrodes ANDE2 may be disposed on (e.g., disposed directly thereon) the first planarization film 160. In an embodiment, the second anode connection electrode ANDE2 may be connected to the first anode connection electrode ANDE1 through a second connection contact hole ANCT2 penetrating through the first planarization film 160. In an embodiment, the second anode connection electrode ANDE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments of the present disclosure are not necessarily limited thereto.

The second planarization film 180 may be disposed on (e.g., disposed directly thereon) the second anode connection electrodes ANDE2. In an embodiment, the second planarization film 180 may be formed as an organic film made of an acrylic resin, an epoxy resin, a phenolic resin, a polyamide resin, a polyimide resin, or the like. However, embodiments of the present disclosure are not necessarily limited thereto.

The light emitting element layer EML including light emitting elements LEL and a bank 190 may be disposed on (e.g., disposed directly thereon) the second planarization film 180. Each of the light emitting elements LEL includes a pixel electrode 171, a light emitting layer 172, and a common electrode 173.

The pixel electrode 171 may be disposed on (e.g., disposed directly thereon) the second planarization film 180. In an embodiment, the pixel electrode 171 may be connected to the second anode connection electrode ANDE2 through a third connection contact hole ANCT3 penetrating through the second planarization film 180.

In a top emission structure in which light is emitted toward the common electrode 173 based on the light emitting layer 172, the pixel electrode 171 may be made of a metal material having high reflectivity, such as a stacked structure (Ti/Al/Ti) of aluminum (Al) and titanium (Ti), a stacked structure (ITO/Al/ITO) of aluminum (Al) and indium tin oxide (ITO), a stacked structure (ITO/Ag/ITO) of silver (Ag) and ITO, an APC alloy, and a stacked structure (ITO/APC/ITO) of an APC alloy and ITO. The APC alloy is an alloy of silver (Ag), palladium (Pd), and copper (Cu). However, embodiments of the present disclosure are not necessarily limited thereto.

The bank 190 may be formed to partition the pixel electrodes 171 on the second planarization film 180 to define first and second light emitting parts EA1 and EA2. The bank 190 may be disposed to cover edges of the pixel electrodes 171. In an embodiment, the bank 190 may be formed as an organic film made of an acrylic resin, an epoxy resin, a phenolic resin, a polyamide resin, a polyimide resin, or the like. However, embodiments of the present disclosure are not necessarily limited thereto.

Each of the first light emitting part EA1 and the second light emitting part EA2 refers to each area in which the pixel electrode 171, the light emitting layer 172, and the common electrode 173 are sequentially stacked and holes from the pixel electrode 171 and electrons from the common electrode 173 are recombined with each other in the light emitting layer 172 to emit light.

The light emitting layer 172 may be disposed on the pixel electrode 171. In an embodiment, the light emitting layer 172 may include an organic material to emit light of a predetermined color. For example, the light emitting layer 172 may include a hole transporting layer, an organic material layer, and an electron transporting layer.

The common electrode 173 may be disposed on the light emitting layer 172. The common electrode 173 may be disposed to cover the light emitting layer 172. In an embodiment, the common electrode 173 may be a common layer formed in common in the first light emitting part EA1 and the second light emitting part EA2. However, embodiments of the present disclosure are not necessarily limited thereto.

In the top emission structure, the common electrode 173 may be made of a transparent conductive material (TCO) such as ITO or indium zinc oxide (IZO) capable of transmitting light therethrough or a semi-transmissive conductive material such as magnesium (Mg), silver (Ag), or an alloy of magnesium (Mg) and silver (Ag). However, embodiments of the present disclosure are not necessarily limited thereto. In an embodiment in which the common electrode 173 is made of the semi-transmissive conductive material, emission efficiency may be increased by a micro cavity.

A spacer 191 may be disposed on the bank 190 (e.g., disposed directly thereon in the third direction DR3). The spacer 191 may serve to support a mask during a manufacturing process of manufacturing the light emitting layer 172. In an embodiment, the spacer 191 may be formed as an organic film made of an acrylic resin, an epoxy resin, a phenolic resin, a polyamide resin, a polyimide resin, or the like. However, embodiments of the present disclosure are not necessarily limited thereto.

In some embodiments, the display panel 400 may further include a capping layer CPL disposed on (e.g., disposed directly thereon) the common electrode 173. The capping layer CPL may include an inorganic material. For example, in an embodiment the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride. However, embodiments of the present disclosure are not necessarily limited thereto.

The encapsulation layer TFEL may be disposed on (e.g., disposed directly thereon) the common electrode 173. In an embodiment, the encapsulation layer TFEL may include at least one inorganic film to prevent oxygen or moisture from penetrating into the light emitting element layer EML. In addition, the encapsulation layer TFEL may include at least one organic film to protect the light emitting element layer EML from foreign substances such as dust. For example, in an embodiment shown in FIG. 7 the encapsulation layer TFEL may include a first encapsulation inorganic film TFE1, an encapsulation organic film TFE2, and a second encapsulation inorganic film TFE3. However, embodiments of the present disclosure are not necessarily limited thereto.

The first encapsulation inorganic film TFE1 may be disposed on (e.g., disposed directly thereon) the common electrode 173, the encapsulation organic film TFE2 may be disposed on (e.g., disposed directly thereon) the first encapsulation inorganic film TFE1, and the second encapsulation inorganic film TFE3 may be disposed on (e.g., disposed directly thereon) the encapsulation organic film TFE2. In an embodiment, the first encapsulation inorganic film TFE1 and the second encapsulation inorganic film TFE3 may be formed as multiple films in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, a polyimide resin, or the like. However, embodiments of the present disclosure are not necessarily limited thereto.

The touch sensing layer TDL may be disposed on the encapsulation layer TFEL (e.g., disposed directly thereon in the third direction DR3). In an embodiment, the touch sensing layer TDL includes a first touch insulating film TINS1, connection electrodes BE, a second touch insulating film TINS2, driving electrodes TE, sensing electrodes RE, and a third touch insulating film TINS3.

The first touch insulating film TINS1 may be disposed on the encapsulation layer TFEL (e.g., disposed directly thereon in the third direction DR3). In an embodiment, the first touch insulating film TINS1 may be formed as an inorganic film such as a silicon nitride layer, a silicon oxynitride layer, a silicon oxide layer, a titanium oxide layer, or an aluminum oxide layer. However, embodiments of the present disclosure are not necessarily limited thereto.

The connection electrodes BE may be disposed on (e.g., disposed directly thereon) the first touch insulating film TINS1. In an embodiment, the connection electrode BE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments of the present disclosure are not necessarily limited thereto.

The second touch insulating film TINS2 may be disposed on the connection electrodes BE (e.g., disposed directly thereon in the third direction DR3). In an embodiment, the second touch insulating film TINS2 may be formed as an inorganic film such as a silicon nitride layer, a silicon oxynitride layer, a silicon oxide layer, a titanium oxide layer, or an aluminum oxide layer. Alternatively, the second touch insulating film TINS2 may be formed as an organic film made of an acrylic resin, an epoxy resin, a phenolic resin, a polyamide resin, a polyimide resin, or the like. However, embodiments of the present disclosure are not necessarily limited thereto.

The driving electrodes TE and the sensing electrodes RE may be disposed on (e.g., disposed directly thereon) the second touch insulating film TINS2. In an embodiment, each of the driving electrodes TE and the sensing electrodes RE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. However, embodiments of the present disclosure are not necessarily limited thereto.

The driving electrode TE and the sensing electrode RE may overlap the connection electrodes BE in the third direction DR3. In an embodiment, the driving electrode TE may be connected to the connection electrode BE through a touch contact hole TCNT1 penetrating through the first touch insulating film TINS1.

The third touch insulating film TINS3 may be formed on (e.g., disposed directly thereon) the driving electrodes TE and the sensing electrodes RE. The third touch insulating film TINS3 may planarize a step formed due to the driving electrodes TE, the sensing electrodes RE, and the connection electrodes BE. In an embodiment, the third touch insulating film TINS3 may be formed as an organic film made of an acrylic resin, an epoxy resin, a phenolic resin, a polyamide resin, a polyimide resin, or the like. However, embodiments of the present disclosure are not necessarily limited thereto.

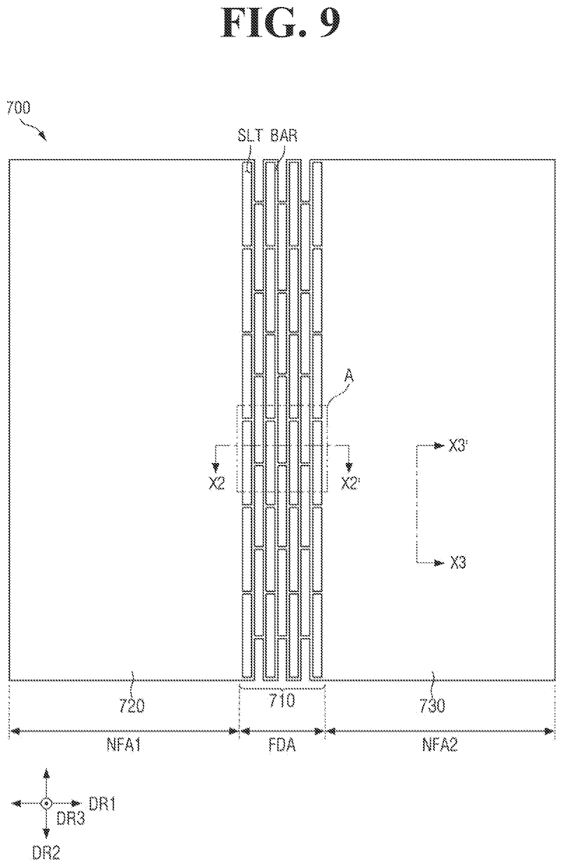

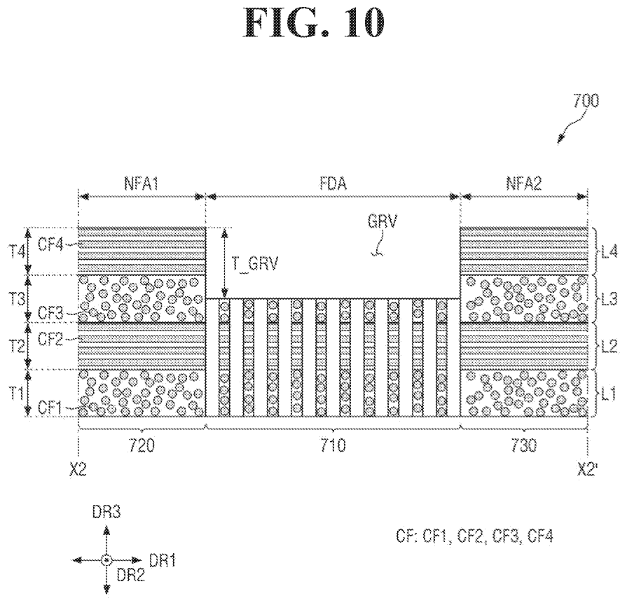

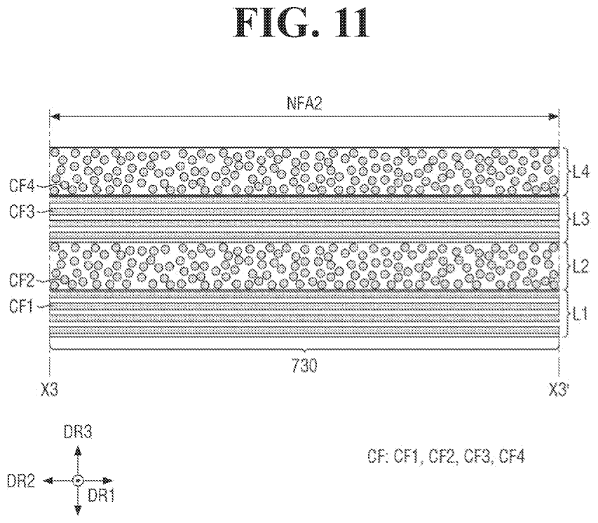

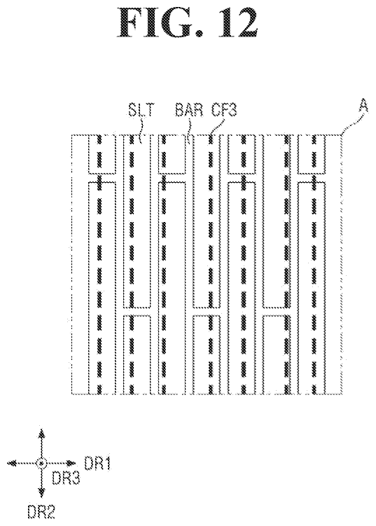

FIG. 8 is a perspective view of a panel support member according to an embodiment. FIG. 9 is a plan view of the panel support member according to an embodiment. FIG. 10 is a cross-sectional view taken along line X2-X2′ of FIG. 9. FIG. 11 is a cross-sectional view taken along line X3-X3′ in FIG. 9. FIG. 12 is an enlarged view of portion A of FIG. 9.

Referring to FIGS. 8 to 12, the panel support member 700 may be made of a polymer including fiber yarns CF including carbon fibers or glass fibers and a resin. In an embodiment in which the fiber yarns CF of the panel support member 700 include the carbon fibers, the resin may be epoxy, polyester, polyamide, polycarbonate, polypropylene, polybutylene, or vinyl ester. In an embodiment in which the fiber yarns CF of the panel support member 700 include the glass fibers, the resin may be epoxy, polyester, polyamide, or vinyl ester. However, embodiments of the present disclosure are not necessarily limited thereto.

The panel support member 700 may include a first layer L1, a second layer L2, a third layer L3, and a fourth layer L4, as illustrated in FIG. 10. In an embodiment, the first layer L1 may be a prepreg including first fiber yarns CF1 extending in the second direction DR2. The second layer L2 may be a prepreg including second fiber yarns CF2 extending in the first direction DR1. The third layer L3 may be a prepreg including third fiber yarns CF3 extending in the second direction DR2. The fourth layer L4 may be a prepreg including fourth fiber yarns CF4 extending in the first direction DR1. However, embodiments of the present disclosure are not necessarily limited thereto and the arrangement of the first to fourth fiber yarns CF1 to CF4 may vary in some embodiments. The prepreg refers to a reinforcing material (e.g., a reinforcing fabric) pre-impregnated with a resin.

In an embodiment, each of the first fiber yarn CF1, the second fiber yarn CF2, the third fiber yarn CF3, and the fourth fiber yarn CF4 may be a carbon fiber yarn or a glass fiber yarn. In an embodiment, a width of each of the first fiber yarn CF1, the second fiber yarn CF2, the third fiber yarn CF3, and the fourth fiber yarn CF4 may be in a range of about 7 μm to about 10 μm. However, embodiments of the present disclosure are not necessarily limited thereto. In an embodiment, the first layer L1, the second layer L2, the third layer L3, and the fourth layer L4 may be stacked by a hot press or an autoclave.

In an embodiment, an extension direction of at least one of the first fiber yarns CF1, the second fiber yarns CF2, the third fiber yarns CF3, and the fourth fiber yarns CF4 may be a direction parallel to an extension direction of the first folding line FL1 (see FIG. 1) and the second folding line FL2 (see FIG. 1).

For example, since an extension direction of the first fiber yarns CF1 of the first layer L1 and the third fiber yarns CF3 of the third layer L3 and an extension direction of the folding lines FL1 and FL2 (see FIG. 1) are the same as each other (e.g., are each in the second direction DR2) the first layer L1 and the third layer L3 may be easily folded when the display device 10 is folded.

In an embodiment, an extension direction of at least one of the first fiber yarns CF1, the second fiber yarns CF2, the third fiber yarns CF3, and the fourth fiber yarns CF4 may be a direction crossing the first folding line FL1 (see FIG. 1) and the second folding line FL2 (see FIG. 1).

For example, in an embodiment in which the panel support member 700 includes only the first layer L1 and the third layer L3 each having the first fiber yarns CF1 and the third fiber yarns CF3, the panel support member 700 may be bent along the second direction DR2. For example, in an embodiment in which the panel support member 700 includes only the first layer L1 and the third layer L3 each having the first fiber yarns CF1 and the third fiber yarns CF3, flatness and rigidity of the panel support member 700 may be low. In the display device 10 according to an embodiment of the present disclosure, the panel support member 700 may include the second layer L2 and the fourth layer L4 each having the second fiber yarns CF2 and the fourth fiber yarns CF4 extending in the first direction DR1 as well as the first layer L1 and the third layer L3, and thus, it is possible to prevent the panel support member 700 from being bent along the second direction DR2 and increase the rigidity of the panel support member 700.

In some embodiments, thicknesses T1, T2, T3, and T4 of the first layer L1, the second layer L2, the third layer L3, and the fourth layer L4 may be the same as each other. For example, in an embodiment each of the thicknesses T1, T2, T3, and T4 of the first layer L1, the second layer L2, the third layer L3, and the fourth layer L4 may be in a range of about 25 μm to about 75 μm. However, embodiments of the present disclosure are not necessarily limited thereto, and in some embodiments the thicknesses T1, T2, T3, and T4 of the first layer L1, the second layer L2, the third layer L3, and the fourth layer L4 may also be different from each other. In an embodiment, an entire thickness of the panel support member 700 may be in a range of about 100 μm to about 300 μm.

It has been illustrated in the drawings that the panel support member 700 includes four layers. However, embodiments of the present disclosure are not necessarily limited thereto. For example, in some embodiments the panel support member 700 may include three or less layers or include five or more layers.

In an embodiment, the panel support member 700 may include a folding part 710, a first non-folding part 720 and a second non-folding part 730, as illustrated in FIG. 9. The folding part 710 may be disposed in the folding area FDA, the first non-folding part 720 may be disposed in the first non-folding area NFA1, and the second non-folding part 730 may be disposed in the second non-folding area NFA2.

The folding part 710 may be a part that is folded when the display device 10 is folded. The folding part 710 may be disposed between the first non-folding part 720 and the second non-folding part 730 in the first direction DR1. The folding part 710 may include a plurality of bars BAR and a plurality of slits SLT disposed between the plurality of bars BAR. In an embodiment, the plurality of bars BAR may include horizontal bars BAR each extending in the first direction DR1 and vertical bars BAR each extending in the second direction DR2.

Each of the plurality of slits SLT may be a hole penetrating through the panel support member 700 in the third direction DR3. In an embodiment, each of the plurality of slits SLT may extend in the second direction DR2. For example, a length of each of the plurality of slits SLT in the second direction DR2 may be greater than a length of each of the plurality of slits SLT in the first direction DR1. The folding part 710 may have increased flexibility by including the plurality of slits SLT. For example, the folding part 710 may be stretched in the first direction DR1 when the display device 10 is folded.

The first non-folding part 720 and the second non-folding part 730 may be parts that are not folded when the display device 10 is folded. The first non-folding part 720 may be disposed on one side of the folding part 710 in the first direction DR1, and the second non-folding part 730 may be disposed on the other side of the folding part 710 in the first direction DR1.

The panel support member 700 may further include a groove GRV disposed on the folding part 710. In an embodiment, the groove GRV may be a groove formed from the fourth layer L4 towards the third layer L3 in the third direction DR3. The groove GRV may provide a space in which the panel lower member 600 (see FIG. 6) may be accommodated inside the panel support member 700.

A thickness T_GRV of the groove GRV may be greater than the thickness of the fourth layer L4. For example, in an embodiment the thickness T_GRV of the groove GRV may be in a range of about 50 μm to about 80 μm. Accordingly, a lower surface of the groove GRV, such as an upper surface of the folding part 710 may overlap the third layer L3 in the first direction DR1. The lower surface of the groove GRV is positioned on the third layer L3, and accordingly, the third fiber yarns CF3 of the third layer L3 may be exposed to the outside.

In the display device 10 according to the present embodiment, an extension direction of the fiber yarns CF and an extension direction of each of the plurality of slits SLT on the upper surface of the folding part 710 exposed by the groove GRV may be the same as each other.

For example, in an embodiment an extension direction of the fourth fiber yarns CF4 of the fourth layer L4 positioned on the uppermost layer may be different from the extension direction of the plurality of slits SLT. When the lower surface of the groove GRV overlaps the fourth layer L4 in the first direction DR1, the extension direction of the fourth fiber yarns CF4 of the fourth layer L4 is different from the extension direction of the plurality of slits SLT, and thus, stress applied to the fiber yarns CF when the slits SLT are processed may be increased. Accordingly, uniformity of the slits SLT may be decreased, and fractures occur in the plurality of bars BAR, such that reliability of the panel support member 700 may be decreased.

On the other hand, as illustrated in FIG. 12, an extension direction of the third fiber yarns CF3 of the third layer L3 may be the same as the extension direction of the plurality of slits SLT. When the lower surface of the groove GRV overlaps the third layer L3 in the first direction DR1, the extension direction of the third fiber yarns CF3 of the third layer L3 is the same as the extension direction of the plurality of slits SLT, and thus, stress applied to the fiber yarns CF when the slits SLT are processed may be reduced. Accordingly, uniformity of the slits SLT may be increased, and fractures that may occur in the plurality of bars BAR may be reduced, such that reliability of the panel support member 700 may be increased.

In some embodiments, the folding part 710 may include three or more layers. For example, in an embodiment the folding part 710 may include a first layer L1, a second layer L2, and a third layer L3. In an embodiment in which the folding part 710 includes only the first layer L1 and the second layer L2 each including fiber yarns CF crossing each other in different directions, the rigidity of the panel support member 700 may be relatively low. On the other hand, by disposing the first layer L1 and the third layer L3 including the fiber yarns CF crossing the fiber yarns CF of the second layer L2 disposed in the middle in a direction different from that of the fiber yarns CF of the second layer L2 on and beneath of the second layer L2, respectively, the rigidity of the panel support member 700 may be increased.

In some embodiments, the extension direction of the fiber yarns CF included in two or more of the layers included in the folding part 710 may be the same as the extension direction of the first and second folding lines FL1 and FL2. Accordingly, the flexibility of the folding part 710 may be increased. However, embodiments of the present disclosure are not necessarily limited thereto, and in an embodiment the extension direction of the fiber yarns CF included in two or more of the layers included in the folding part 710 may be different from the extension direction of the first and second folding lines FL1 and FL2. Accordingly, the rigidity of the folding part 710 may be increased.

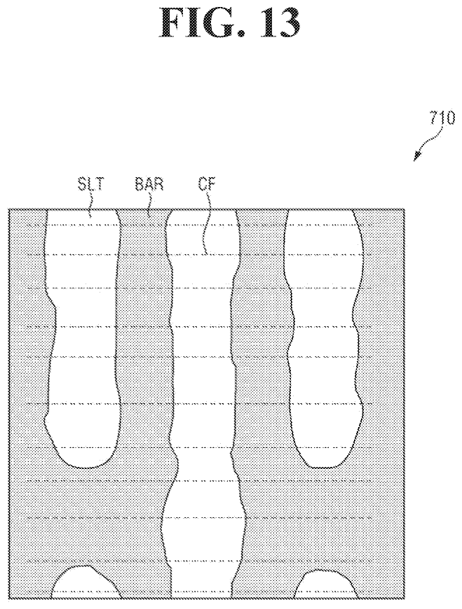

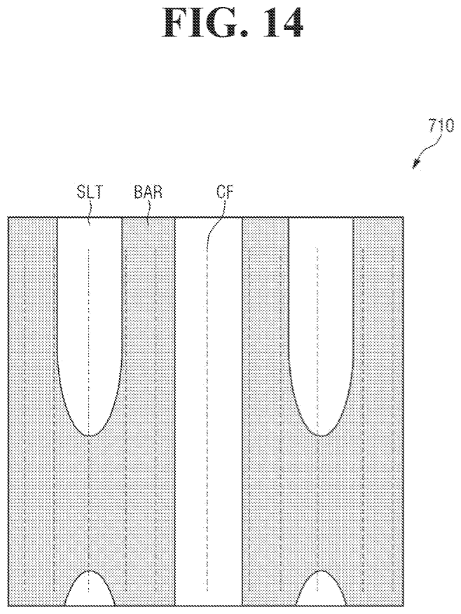

FIG. 13 is an enlarged view of a folding part of a display device according to a comparative embodiment. FIG. 14 is an enlarged view of a folding part of the display device according to an embodiment. FIGS. 13 and 14 are enlarged views illustrating upper surfaces of the folding parts.

Referring to FIGS. 13 and 14 in addition to FIGS. 9 and 10, a display device 10 according to a comparative embodiment may not include the fourth layer LA. For example, the display device 10 according to a comparative embodiment may include only the first layer L1, the second layer L2, and the third layer L3. In the display device 10 according to a comparative embodiment, the lower surface of the groove GRV, such as the upper surface of the folding part 710 may overlap the second layer L2 in the first direction DR1. Alternatively, the display device 10 according to a comparative embodiment may include the fourth layer LA, but may not include the groove GRV, or the upper surface of the folding part 710 may overlap the fourth layer L4 in the first direction DR1.

In the display device 10 according to a comparative embodiment, an upper surface of the second layer L2 or the fourth layer L4 may be exposed to the outside. In this case, the extension direction of the fiber yarns CF of the second layer L2 or the fourth layer L4 is different from the extension direction of the plurality of slits SLT, and thus, stress applied to the fiber yarns CF when the slits SLT are processed may be increased. Accordingly, as illustrated in FIG. 13, uniformity of the slits SLT may be decreased (e.g., curved surfaces may be formed at edges of the slits SLT), and fractures occur in the plurality of bars BAR, such that reliability of the panel support member 700 may be decreased.

On the other hand, in the display device 10 according to an embodiment of the present disclosure when the third layer L3 is exposed to the outside by the groove GRV, the extension direction of the fiber yarns CF of the third layer L3 is the same as the extension direction of the plurality of slits SLT, and thus, stress applied to the fiber yarns CF when the slits SLT are processed may be reduced. Accordingly, as illustrated in FIG. 14, uniformity of the slits SLT may be increased, and fractures that may occur in the plurality of bars BAR may be reduced, such that reliability of the panel support member 700 may be increased.

Hereinafter, embodiments of the display device will be described. In the following embodiments, the same components as those of the above-described embodiment will be denoted by the same reference numerals, and an overlapping description of similar or identical elements may be omitted or simplified and contents different from those described above will be mainly described for economy of explanation.

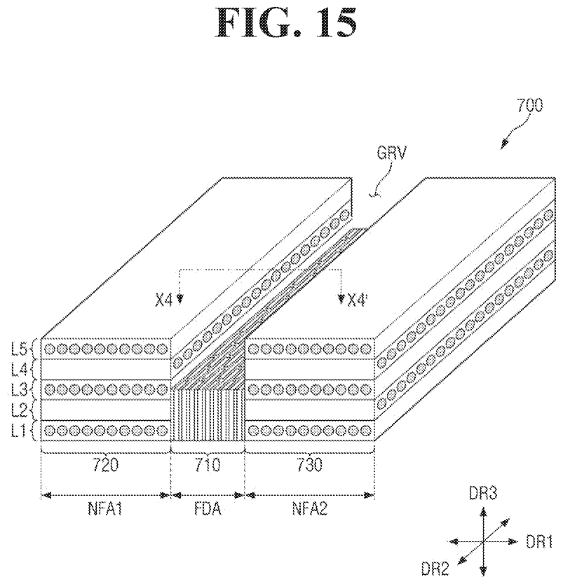

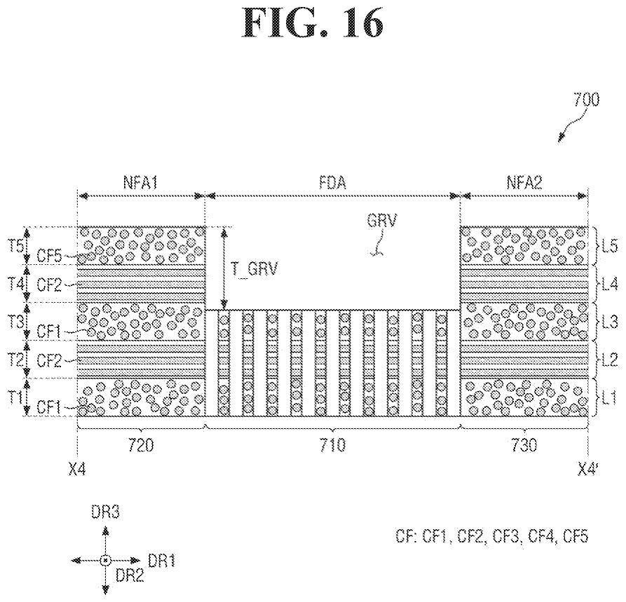

FIG. 15 is a perspective view of a panel support member according to an embodiment. FIG. 16 is a cross-sectional view taken along line X4-X4′ in FIG. 15.

Referring to FIGS. 15 and 16, a display device 10 according to an embodiment is different from the display device 10 according to an embodiment described with reference to FIG. 8 and the like in that it further includes a fifth layer L5.

More specifically, in the display device 10 according to embodiments shown in FIGS. 15-16, the panel support member 700 may further include the fifth layer L5. In an embodiment, the fifth layer L5 may be a prepreg including fifth fiber yarns CF5 extending in the second direction DR2.

The fifth fiber yarn CF5 may be a carbon fiber yarn or a glass fiber yarn. In an embodiment, a width of the fifth fiber yarn CF5 may be in a range of about 7 μm to about 10 μm. However, embodiments of the present disclosure are not necessarily limited thereto. In an embodiment, the fifth layer L5 may be stacked on the fourth layer L4 by a hot press or an autoclave.

An extension direction of the fifth fiber yarns CF5 may be a direction parallel to the extension direction of the first folding line FL1 (see FIG. 1) and the second folding line FL2 (see FIG. 1). The extension direction of the fifth fiber yarns CF5 is the same the extension direction of the first folding line FL1 (see FIG. 1) and the second folding line FL2 (see FIG. 1), and thus, the fifth layer L5 may be easily folded when the display device 10 is folded.

In some embodiments, thicknesses T1, T2, T3, T4, and T5 of the first layer L1, the second layer L2, the third layer L3, the fourth layer L4, and the fifth layer L5 may be the same as each other. For example, in an embodiment each of the thicknesses T1, T2, T3, T4, and T5 of the first layer L1, the second layer L2, the third layer L3, the fourth layer L4, and the fifth layer L5 may be in a range of about 20 μm to about 60 μm. However, embodiments of the present disclosure are not necessarily limited thereto. For example, in some embodiments the thicknesses T1, T2, T3, T4, and T5 of the first layer L1, the second layer L2, the third layer L3, the fourth layer L4, and the fifth layer L5 may also be different from each other. In an embodiment, an entire thickness of the panel support member 700 may be in a range of about 100 μm to about 300 μm.

The groove GRV may be a groove formed from the fifth layer L5 towards the third layer L3 in the third direction DR3. A thickness T_GRV of the groove GRV may be greater than the sum of the thicknesses of the fourth layer L4 and the fifth layer L5. For example, in an embodiment the thickness T_GRV of the groove GRV may be in a range of about 40 μm to about 150 μm. Accordingly, a lower surface of the groove GRV, such as an upper surface of the folding part 710 may overlap the third layer L3 in the first direction DR1. The lower surface of the groove GRV is positioned on the third layer L3, and accordingly, the third fiber yarns CF3 of the third layer L3 may be exposed to the outside.

In the display device 10 according to an embodiment, an extension direction of the fiber yarns CF and an extension direction of each of the plurality of slits SLT on the upper surface of the folding part 710 exposed by the groove GRV may be the same as each other.

For example, an extension direction (e.g., the second direction DR2) of the third fiber yarns CF3 of the third layer L3 exposed by the groove GRV may be the same as the extension direction (e.g., the second direction DR2) of the plurality of slits SLT. The extension direction of the third fiber yarns CF3 of the third layer L3 is the same as the extension direction of the plurality of slits SLT, and thus, stress applied to the fiber yarns CF when the slits SLT are processed may be reduced. Accordingly, uniformity of the slits SLT may be increased, and fractures that may occur in the plurality of bars BAR may be reduced, such that reliability of the panel support member 700 may be increased.

In the display device 10 according to an embodiment described with reference to FIG. 8 and the like, an embodiment in which the panel support member 700 includes four layers has been described by way of example, and in the display device 10 according to an embodiment described with reference to FIG. 15 and the like, a case where the panel support member 700 includes five layers has been described by way of example. However, embodiments of the present disclosure are not necessarily limited thereto and the number of layers included in the panel support member 700 may vary.

For example, the panel support member 700 may include even-numbered or odd-numbered layers. The panel support member 700 may include four or more layers. Regardless of the number of layers included in the panel support member 700, the upper surface of the folding part 710 of the panel support member 700 may be positioned at the same height as a layer including fiber yarns CF extending in the same direction as the extension direction of the plurality of slits SLT. Depending on the thickness T_GRV of the groove GRV, the upper surface of the folding part 710 may be positioned at the same height as the layer including the fiber yarns CF extending in the same direction as the extension direction of the plurality of slits SLT.

Accordingly, stress applied to the fiber yarns CF when the slits SLT of the folding part 710 are processed may be reduced. Accordingly, uniformity of the slits SLT may be increased, and fractures that may occur in the plurality of bars BAR may be reduced, such that reliability of the panel support member 700 may be increased.

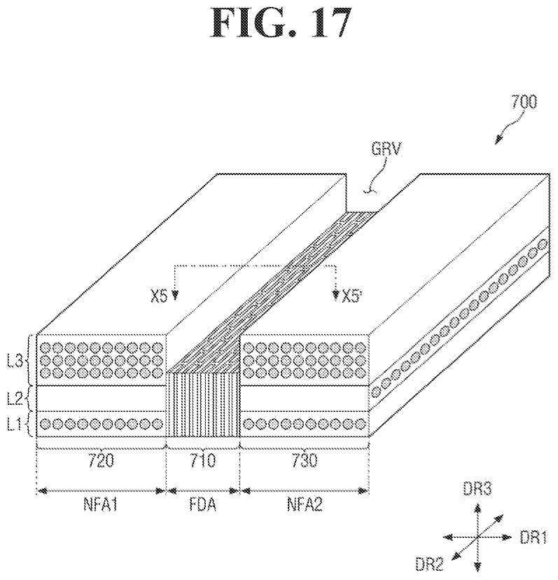

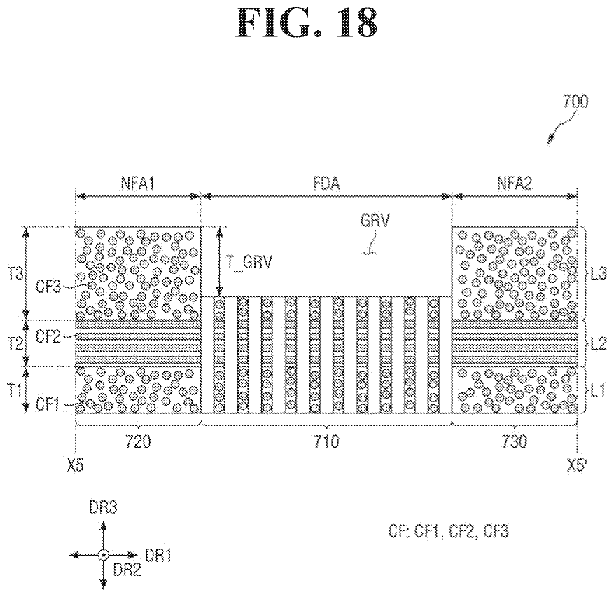

FIG. 17 is a perspective view of a panel support member according to an embodiment. FIG. 18 is a cross-sectional view taken along line X5-X5′ of FIG. 17.

Referring to FIGS. 17 and 18, a display device 10 according to an embodiment is different from the display devices 10 according to embodiments described above with reference to FIGS. 8 and 15 and the like in that a thickness of the uppermost layer of the panel support member 700 is greater than thicknesses of other layers.

More specifically, the panel support member 700 may include a first layer L1, a second layer L2, and a third layer L3 (e.g., consecutively stacked in the third direction DR3). The first layer L1 may be a prepreg including first fiber yarns CF1 extending in the second direction DR2. The second layer L2 may be a prepreg including second fiber yarns CF2 extending in the first direction DR1. The third layer L3 may be a prepreg including third fiber yarns CF3 extending in the second direction DR2.

The thickness of the uppermost layer of the panel support member 700 may be greater than the thicknesses of the other layers of the panel support member 700. For example, a thickness T3 of the third layer L3 may be greater than thicknesses of the first layer L1 and the second layer L2. In an embodiment, each of thicknesses T1 and T2 of the first layer L1 and the second layer L2 may be in a range of about 25 μm to about 75 μm. The thickness of the third layer L3 may be in a range of about 50 μm to about 150 μm. An entire thickness of the panel support member 700 may be in a range of about 100 μm to about 300 μm.

The thickness of the third layer L3 may be greater than the thickness T_GRV of the groove GRV. Accordingly, a lower surface of the groove GRV, such as an upper surface of the folding part 710 may overlap the third layer L3 in the first direction DR1. The lower surface of the groove GRV is positioned at a same height (e.g., in the third direction DR3) as the third layer L3, and accordingly, the third fiber yarns CF3 of the third layer L3 may be exposed to the outside.

In the display device 10 according to an embodiment, an extension direction of the fiber yarns CF and an extension direction of each of the plurality of slits SLT on the upper surface of the folding part 710 exposed by the groove GRV may be the same as each other.

For example, an extension direction (e.g., the second direction DR2) of the third fiber yarns CF3 of the third layer L3 exposed by the groove GRV may be the same as the extension direction (e.g., the second direction DR2) of the plurality of slits SLT. The extension direction of the third fiber yarns CF3 of the third layer L3 is the same as the extension direction of the plurality of slits SLT, and thus, stress applied to the fiber yarns CF when the slits SLT are processed may be reduced. Accordingly, uniformity of the slits SLT may be increased, and fractures that may occur in the plurality of bars BAR may be reduced, such that reliability of the panel support member 700 may be increased.

Unlike the display device 10 according to an embodiment described with reference to FIG. 8 and the like, in the display device 10 according to embodiments shown in FIGS. 17-18, by adjusting the thickness T3 of the third layer L3 instead of including the fourth layer L4, the upper surface of the folding part 710 may be positioned at the same height as the layer including the fiber yarns CF extending in the same direction as the extension direction of the plurality of slits SLT.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A display device comprising:
a display panel that is foldable based on a folding line extending in a first direction; and
a support member disposed on a first surface of the display panel, the support member including a folding part that is stretched when the display panel is folded, a first non-folding part and a second non-folding part disposed on a first side and an opposite second side of the folding part, respectively, and a groove disposed on the folding part, wherein:
the folding part includes a plurality of slits and a plurality of bars disposed between the plurality of slits,
the support member includes fiber yarns extending in the first direction and fiber yarns extending in a second direction crossing the first direction,
the fiber yarns extending in the first direction and the fiber yarns extending in the second direction are alternately stacked along a thickness direction of the support member, and
the plurality of slits and the fiber yarns on an upper surface of the folding part exposed by the groove have a same extension direction as each other.

2. The display device of claim 1, wherein the folding line has a same extension direction as the extension direction of the plurality of slits.

3. The display device of claim 1, wherein thicknesses of each of the first non-folding part and the second non-folding part are greater than a thickness of the folding part.

4. The display device of claim 1, wherein the support member includes:
a first layer having first fiber yarns extending in the first direction;
a second layer disposed directly on the first layer and having second fiber yarns extending in the second direction crossing the first direction;
a third layer disposed directly on the second layer and having third fiber yarns extending in the first direction; and
a fourth layer disposed directly on the third layer and having fourth fiber yarns extending in the second direction,
wherein the upper surface of the folding part is positioned at a same height as the third layer.

5. The display device of claim 4, wherein a thickness of the groove is greater than a thickness of the fourth layer.

6. The display device of claim 5, wherein:
the thickness of the groove is in a range of about 50 μm to about 80 μm; and
the thickness of the fourth layer is in a range of about 25 μm to about 75 μm.

7. The display device of claim 4, wherein the groove overlaps the third layer and the fourth layer.

8. The display device of claim 4, wherein the first layer, the second layer, the third layer, and the fourth layer have a same thickness as each other.

9. The display device of claim 4, wherein:
the support member further includes a fifth layer disposed directly on the fourth layer, the fifth layer having fifth fiber yarns extending in the first direction; and
the groove further overlaps the fifth layer.

10. The display device of claim 9, wherein a thickness of the groove is greater than a sum of thicknesses of the fourth layer and the fifth layer.

11. The display device of claim 4, wherein the folding part is positioned at a same height as the first layer, the second layer, and the third layer.

12. The display device of claim 1, further comprising a lower member disposed between the display panel and the support member,
wherein the lower member is disposed within the groove.

13. The display device of claim 12, wherein the lower member includes at least one of a light blocking layer, a buffer layer, and a shielding layer.

14. The display device of claim 1, further comprising a digitizer member disposed on a surface of the support member,
wherein the digitizer member overlaps the first non-folding part and the second non-folding part.

15. The display device of claim 1, wherein the support member includes:
a first layer having first fiber yarns extending in the first direction;
a second layer disposed on the first layer and having second fiber yarns extending in the second direction crossing the first direction; and
a third layer disposed on the second layer and having third fiber yarns extending in the first direction,
wherein a thickness of the third layer is greater than thicknesses of the first layer and the second layer.

16. The display device of claim 15, wherein a thickness of the groove is less than the thickness of the third layer.

17. The display device of claim 1, wherein the fiber yarns include at least one of carbon fibers and glass fibers.

18. A display device comprising:
a display panel including a folding area, a first non-folding area disposed on a first side of the folding area, and a second non-folding area disposed on an opposite second side of the folding area; and
a support member disposed on a first surface of the display panel, the support member including a groove disposed in the folding area and a folding part disposed below the groove, wherein the folding part includes a plurality of slits,
the support member includes:
a first layer having first fiber yarns extending in a first direction;
a second layer disposed on the first layer and having second fiber yarns extending in a second direction crossing the first direction; and
a third layer disposed on the second layer and having third fiber yarns extending in the first direction, and
the plurality of slits exposed by the groove extends in the first direction.

19. The display device of claim 18, wherein an upper surface of the folding part is positioned at a same height as the third layer.

20. The display device of claim 18, further comprising a lower member disposed between the display panel and the support member,
wherein the lower member is disposed within the groove.
